(19) United States
(12) Patent Application Publication
(10) Pub. No.: US 2008/0099238 A1
(43) Pub. Date: May 1, 2008

(54) INTEGRATED CIRCUIT INCLUDING PRINTED CIRCUIT BOARD FOR A MEMORY MODULE AND METHOD FOR MANUFACTURING

(75) Inventor: Srdjan Djordjevic, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Qimonda AG, Muenchen (DE)

(21) Appl. No.: 11/925,370

(22) Filed: Oct. 26, 2007

(30) Foreign Application Priority Data
Oct. 27, 2006 (DE) 10 2006 050 882.3

(51) Int. Cl. H05K 9/00; H01R 43/00; H05K 1/11

(52) U.S. Cl. 174/350; 174/262; 174/260; 29/825

(57) ABSTRACT

A printed circuit board for a memory module is disclosed. The printed circuit board provides inner layers, at least one middle layer with at least one large-area conductor structure for guiding a respective substantially constant electric potential. On a first and/or second inner layer directly above or below the middle layer, first or second high speed conductor structures are arranged to guide first or second high speed signals over the largest share of their guidance on the printed circuit board. Arranged on a top and/or bottom layer are: contacting conductor structures for at least one device, printed circuit board input and printed circuit board output contact terminals and short conductor structures which are each connected with predetermined ones of the printed circuit board input and/or printed circuit board output contact terminals or predetermined ones of the first and/or second high speed conductor structures through vias between the layers.

### CROSS-REFERENCE TO RELATED APPLICATIONS

This Utility patent application claims priority to German Patent Application No. DE 10 2006 050 882.3 filed on Oct. 27, 2006, which is incorporated herein by reference.

### BACKGROUND

One embodiment relates to a printed circuit board for a memory module, to a memory module, a memory module system, and to a method for manufacturing a printed circuit board for a memory module.

Such memory modules are used in commercial computers, for instance, PCs (personal computers), laptops, notebooks, workstation computers, server computers, etc. For example, for equipping the above-mentioned computers with a main memory, the main printed circuit board, the motherboard, in general includes one or several breadboard socket terminal strips for the memory modules mentioned, as well as one or several memory control processors (memory controllers) which coordinate the write and read accesses to memory devices of the memory modules by one or several CPU(s) (CPU=central processing unit), i.e. main processors of the computers.

The different components of the motherboard, e.g., the above-mentioned memory modules, the CPU, the memory controller, etc. are—for the exchange of corresponding data, address, and/or control signals—for example, connected with each other through one or a plurality of bus systems.

As memory modules that are adapted to be plugged into the above-mentioned breadboard socket terminal strips, appropriate SIMM or DIMM memory cards are, for instance, suitable (SIMM=Single In-Line Memory Module, DIMM=Dual In-Line Memory Module), which each include a plurality of memory devices, e.g., a plurality of RAM memory devices, in one embodiment SRAMs or DRAMs (SRAM=Static Random Access Memory, DRAM=Dynamic Random Access Memory).

In one or more embodiments, the above-mentioned memory modules, memory modules with upstream data buffer devices (buffers) may be used in a plurality of applications—in one embodiment, for instance, in server or workstation computers—, e.g., “buffered DIMMs” or “FB-DIMMs” (FB-DIMM=Fully Buffered DIMM), etc.

A memory module, e.g., an “FB-DIMM”, includes memory devices on both sides of a printed circuit board. The controlling of the memory devices is performed by a control device. For controlling the memory devices, the control device includes a hub chip as a driver/control chip. For example, the control device and the memory devices include a “BGA” (Ball-Grid-Array) package for increasing the contact density of the packages of the devices and for their easier contacting with the printed circuit board.

In a planar design of an “FBDIMM” memory module printed circuit board, each of the memory devices includes exactly one memory chip. The memory chips, for example, include DRAM (Dynamic Random Access Memory) memory cells.

DRAM memory cells are typically arranged in the form of a matrix within a memory cell field along word lines and bit lines. The basic elements of a DRAM memory cells are a select transistor, for example, a field effect transistor, and a memory capacitor. The control contacts of the select transistors (e.g., gate contacts) of a particular column of the memory cell field are each connected with a particular word line. The one of the controlled contacts of the select transistors (e.g., the source contact of an n-channel field effect transistor) is connected with the memory capacitor of the respective memory cell. The other of the controlled contacts of the select transistors (e.g., the drain contact of an n-channel field effect transistor) of a particular row of the memory cell field is respectively connected with a particular bit line.

Information may be read out from the memory cell or be written into the memory cell, respectively, in that a suitable control signal on the word line switches the select transistor in the conductive state and thus connects the memory capacitor with the corresponding bit line. In the case of a read access, the charge state of the memory capacitor may be read out through the bit line, or in the case of a write access, a charge state may be stored in the memory capacitor.

The above-mentioned read and write accesses to the memory cells of the memory chips are performed in that the hub chip of the control device is controlled by a memory controller. For communication between the memory controller with the control device on the “FBDIMM” memory module, a bus is used which includes, in one embodiment, primary and secondary high speed signals. To this end, the control device includes receivers and transmitters which receive predetermined ones of the primary high speed signals or transmit other predetermined ones of the primary high speed signals, respectively, and receive predetermined ones of the secondary high speed signals or transmit other predetermined ones of the secondary high speed signals, respectively.

The bus is contacted with the breadboard socket terminal strip through the printed circuit board contact terminals that are arranged on the front and rear sides of the plugged-in printed circuit board of the memory module at the longitudinal edge thereof in the form of a contact terminal strip. In the case of a plurality of busses between the memory controller and the control device it may be provided to supply the signals of particular busses to the contact terminals on the front side of the printed circuit board and the signals of other particular busses to the contact terminals on the rear side of the printed circuit board.

The designation “DIMM” (=Dual In-Line Memory Module) memory module comes from the fact that contact terminals on the front and rear sides of the printed circuit board for a memory module have different signals in contrast to “SIMM” (=Single In-Line Memory Module) memory modules. Through the at least one bus, in one embodiment control signals may also be transmitted to the control device and be received from the control device. To this end, the bus lines are, through the contact terminals of the control device, both connected with transmitters (Tx transmitters) and with receivers (Rx receivers) in the hub chip of the control device.

The front side of the plugged-in printed circuit board for a memory module is equivalent to the upper side of the printed circuit board for a memory module illustrated in cross-section in FIG. 5, which illustrates the layer structure of the printed circuit board for a memory module. Correspondingly, the rear side of the plugged-in printed circuit board for a memory module is equivalent to the bottom side of the printed circuit board for a memory module in the cross-sectional representation of FIG. 5.

As the CPU performance increases, the requirements to the data transmission rate between the memory module and the motherboard and thus also to the data transmission rate between the control device and the memory controller also increase. This data transmission rate is, on the one hand, determined by the memory clock rates of the memory chips, which are usually in the three-figure MHz range. Higher data transmission rates by using higher memory clock rates often still have to face technological limits.

Therefore, the “DDR” (Double Data Rate) technology is, for example, used for increasing the data transmission rate between the memory module and the motherboard, in which the data from or to the memory module are transmitted both at the falling and at the rising edges of the memory clock.

The follower technologies “DDR2” and “DDR3” again increase the data transmission rate mentioned in that the clock rates of the input and output drivers of the memory module are doubled or quadrupled vis-à-vis the respective memory clock rate. Thus, through the individual bus lines of the bus mentioned, it is already possible to achieve correspondingly high data rates in the three-figure MB/s range, on the bus altogether in the Gb/s range.

To maintain the signal integrity of the individual bus signals on the printed circuit board for a memory module, to minimize the crosstalk from or to other signals as well as the coupling-in of interferences, the high-rate bus signals are, for example, guided through specific high speed conductor structures, in one embodiment through differential bus conductor path pairs on the printed circuit board for a memory module between the printed circuit board contact terminals and the control device.

The space for this guidance of conductor paths depends, even if multi-layer printed circuit boards for a memory module are used, on how many and how tightly the memory devices are placed on the printed circuit board for a memory module. In the case of a “stacked” design of an “FBDIMM” memory module instead of a planar design, two memory chips (“dual stacked”) or four memory chips (“quad stacked”) are each arranged in a stacked manner within the memory devices. The stacked arrangement of the memory chips renders it possible, with equal storage capacity, to place only one respective row with memory devices on the upper and lower sides of the memory module.

In correspondence with a standard, in the case of a “stacked” design of a memory module, the feeding of input signals present at printed circuit board input contact terminals of a first bus to the control device is performed through conductor paths that are arranged on the upper side of the printed circuit board, i.e., as a rule, on the side at which the control device is also positioned. In analogy, output signals of the control device are fed to printed circuit board output contact terminals of the first bus on the upper side of the printed circuit board through conductor paths that are arranged on the upper side of the printed circuit board.

In contrast to this, the input signals of a second bus which are, in correspondence with the standard mentioned, to be fed to the printed circuit board input contact terminals on the lower side of the printed circuit board, are, through short conductor paths, “stubs” on the lower side of the printed circuit board, connected with a via guided through the printed circuit board (“far side-by-side via”). It connects the printed circuit board input contact terminals of the second bus with conductor paths that are arranged on one of predetermined inner layers of the multi-layer printed circuit board.

In the vicinity of the control device, the conductor paths of the inner layers are, through a further via, connected with a short conductor piece on the upper side of the printed circuit board, which finally feeds the input signals of the second bus to the control device.

In analogy, the signals to be fed from the control device to the printed circuit board output contact terminals of the second bus on the lower side of the printed circuit board are, through a further short conductor piece on the upper side of the printed circuit board and a further via, guided up to one of predetermined inner layers of the printed circuit board. On the inner layer of the printed circuit board, a conductor path is connected with the latter-mentioned via, wherein the conductor paths leads up to a further via. This via is connected with a further short conductor piece on the lower side of the printed circuit board, said further short conductor piece serving as a supply line to the printed circuit board output contact terminal of the second bus.

The above-described feeding of signals from the memory controller to the control device or from the control device to the memory controller, respectively, can, however, not be realized in the case of an “FBDIMM” memory module of planar design due to a lack of space in one embodiment for high speed conductor structures in the layers mentioned.

FIG. 3 illustrates a section of a layer of a printed circuit board for a “FBDIMM” memory module. The symbolic contour of the control device 20 is illustrated at the right; the smaller symbolic contours illustrated in two rows at the left of the control device indicate the positioning of the memory devices 30. Furthermore, at the lower edge of the layer of the printed circuit board, the printed circuit board input and the printed circuit board output contact terminals 112, to which the bus is connected which connects the “FBDIMM” memory module with the memory controller, are indicated by contact terminal pads. The entirety of contact terminal pads for the printed circuit board input and the printed circuit board output contact terminals 112 indicates the contact terminal strip 100.

As is illustrated by the narrow corridor 125 between the lower row of the contours of the memory devices 30 and the indicated contact terminal strip 100, there is only little space available for the high speed conductor structures on this layer of the printed circuit board. Therefore, it is only possible to arrange some of the conductor paths leading from the printed circuit board input contact terminals to the control device and only some of the conductor paths leading back from the control device to the printed circuit board output contact terminals on the illustrated layer of the printed circuit board. The remaining printed circuit board input and printed circuit board output contact terminals are supplied to the control device or returned from the control device to the printed circuit board output contact terminals, respectively, through conductor paths that are positioned on inner layers of the multi-layer printed circuit board. To this end, the printed circuit board input and printed circuit board output contact terminals are in turn connected through short conductor pieces with vias that extend from the upper side, i.e. the top layer, to the lower side, i.e. the bottom layer of the printed circuit board. Through these vias, the printed circuit board input and printed circuit board output contact terminals are connected with the conductor paths on the inner layers of the printed circuit board. In the region of the control device, further vias are arranged through which the signals are guided from the conductor paths on the inner layers back to the upper side of the printed circuit board. There, they may be directly supplied to the control device, i.e. merely through contacting conductor structures of the control device.

In the case of printed circuit boards for conventional memory modules, in one embodiment for highly integrated memory modules, the guidance of the high-speed signals (1 HS, 2 HS) of the bus is therefore, so as to gain space, distributed over several inner layers, as is illustrated by the layer structure for a “DDR2” “FBDIMM” memory module in FIG. 4. On the one hand, the high speed signals that are distributed over the layers in this way have nevertheless relatively little space available for guidance on the individual layers. This is because, as is illustrated by the high conductor structure density in the layer Lay 1 or the layer Lay 8 of a known memory module in FIG. 1 and FIG. 2, many other signals are also guided through the respective layers. Furthermore, due to the spatial vicinity of the conductor structures for the other signals, crosstalk of these signals to the high speed signals, and vice versa, also occurs.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 a schematic top view of a section of a top layer Lay 1 of a printed circuit board for a “DDR2” “FBDIMM” memory module.

FIG. 2 a schematic top view of a section of a bottom layer Lay 8 of a printed circuit board for a “DDR2” “FBDIMM” memory module.

FIG. 3 a schematic top view of a section of a top layer of another printed circuit board for a memory module.

FIG. 4 a schematic cross-sectional view of the layer structure and of the signal distribution on a printed circuit board for a “DDR2” “FBDIMM” memory module.

FIG. 5 a schematic cross-sectional view of the layer structure and of the signal distribution on a printed circuit board for a “DDR3” “FBDIMM” memory module according to an embodiment.

### DETAILED DESCRIPTION

In the following Detailed Description, reference is made to the accompanying drawings, which form a part hereof, and in which is illustrated by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One embodiment provides a printed circuit board, in one embodiment for a memory module, a memory module, a memory module system, and a method for manufacturing a printed circuit board, in one embodiment for a memory module.

One embodiment provides a printed circuit board, in one embodiment for a memory module, for example, for a “DDR2” or “DDR3” “FBDIMM” memory module. It includes a top and a bottom layer as well as a plurality of stacked inner layers therebetween, each with predetermined conductor structures.

The inner layers include at least one middle layer with at least a large-area conductor structure for carrying a respective substantially constant electric potential. For example, the substantially constant electric potential is a supply voltage potential for at least one device to be arranged on the printed circuit board such as—in the case of a printed circuit board for a memory module—in one embodiment a control device and one or a plurality of memory devices.

In one example, at least one large-area conductor structure carries the positive voltage supply potential for the at least one device, in one embodiment for an integrated semiconductor device with field effect transistors, the positive voltage supply potential of which is usually identified by VDD. Alternatively, the at least one or a further large-area conductor structure of the at least one middle layer also carries the positive supply voltage potential for another device, in one embodiment for an integrated semiconductor device with bipolar transistors, the positive supply voltage potential of which is usually identified by VCC.

Finally, the at least one or a further large-area conductor structure of the at least one middle layer may also be destined for carrying the mass potential that is usually identified by GND (Ground).

In one embodiment, the printed circuit board includes a first inner layer directly above the middle layer, or, in the case of a plurality of middle layers, above the top middle layer.

On the first inner layer, at least predetermined first high speed conductor structures are arranged which are destined to guide first high speed signals over the major share of the guidance on the printed circuit board between predetermined contacting conductor structures of the at least one device and predetermined printed circuit board input and printed circuit board output contact terminals on the top and/or the bottom layer.

Correspondingly, the printed circuit board includes a second inner layer directly below the middle layer or, in case of a plurality of middle layers, below the bottom middle layer.

On the second inner layer, at least predetermined second high speed conductor structures are arranged which are destined to guide second high speed signals over the major share of their guidance on the printed circuit board between predetermined ones of the contacting conductor structures of the at least one device and predetermined ones of the printed circuit board input and printed circuit board output contact terminals on the top and/or the bottom layer.

The above-mentioned layer structure in which, for guiding the high speed signals, specific layers are provided with the first and the second inner layers on which, if possible, no or as few other conductor structures as possible are provided in addition to the first and second high speed conductor structures.

Thus, on the one hand, substantially no crosstalk to other signals takes place in the corresponding first and second inner layers. On the other hand, the space available for the guidance of additional high speed conductor structures on the first or second layers, in one embodiment for printed circuit boards of recent memory module generations, is increased. Finally, the specific inner layers for high speed conductor structures have correspondingly fewer layers that have to be provided for conductor structures with ground potential faces than in the case of the guidance of the high speed signals distributed over a plurality of layers.

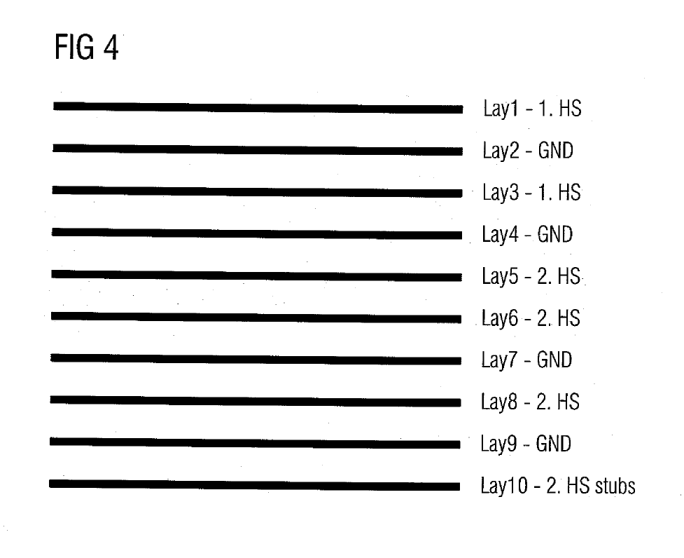

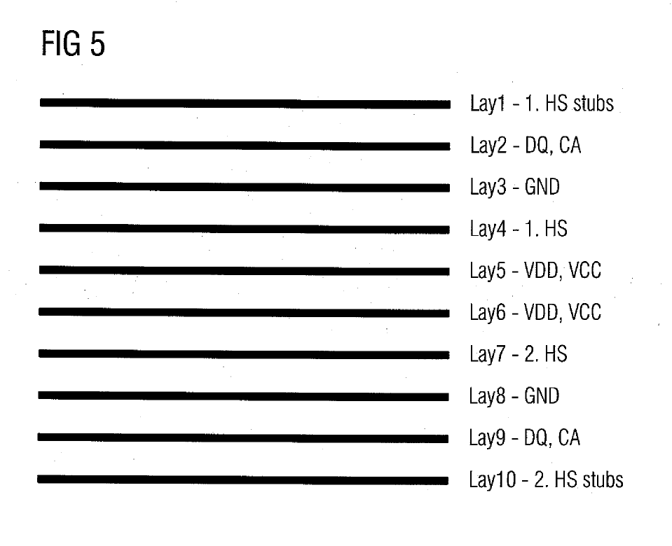

In the example of the novel layer structure of the printed circuit board in FIG. 5, the layers Lay 2 and Lay 9 with ground potential faces GND may thus be omitted vis-à-vis the layer structure in FIG. 4. This is because in the layer structure according to FIG. 5 it is in one embodiment not also the layers Lay 3 and Lay 8 that serve to guide the first (1 HS) or second (2 HS) high speed signals as is the case in the layer structure according to FIG. 4.

Instead, in the novel layer structure according to FIG. 5, conductor structures in the form of ground potential faces are arranged on the layers Lay 3 and Lay 8. These large-area conductor structures serve both the first high speed conductor structures on the layer Lay 4 and/or the second high speed conductor structure on the layer Lay 7, as well as the conductor structures for the guiding of further signals (DQ, CA, CTRL, CLK), in one embodiment further bus signals, on the layers Lay 2 or Lay 9 as ground potential faces.

The novel, at least one middle layer for guiding a respective substantially constant electric potential is thus positioned between the first and the second inner layers which are destined for the predominant guidance of the first and/or second high speed signals.

On the one hand, the above-mentioned large-area conductor structures of the at least one middle layer may serve to substantially reduce a crosstalk between the first and second high speed signals. In one embodiment, memory modules have an own inner layer that is each used for the guidance of the first and second high speed signals.

On the other hand, the guiding of the supply voltage potentials such as VDD and VCC through the above-mentioned large-area conductor structures allows for small impedances in the supply voltage paths on the printed circuit board, and thus for small voltage losses across the parasitic supply impedances. Thus, the corresponding device have, at the corresponding contacting conductor structures, an efficient supply voltage available for the corresponding supply voltage potential on the printed circuit board, which lies thus less below the nominal supply voltage. This enables a more reliable operation of the devices, in one embodiment of semiconductor memory devices of recent generations with very low supply voltages.

Furthermore, at least the following structures are arranged on the top and/or bottom layers: On the one hand, a plurality of contacting conductor structures for the at least one device, in one embodiment the control device and one or a plurality of memory devices with a printed circuit board for a memory module.

Contacting conductor structures in the above-mentioned meaning are conductor structures that have been designed in a predetermined manner and that are assigned to predetermined contact elements of a device. They enable the device to be placed on the printed circuit board in an automated assembling process and to be connected conductively with the respective contacting conductor structures by using common contacting technologies such as, in one embodiment, soldering. In one example, the at least one device includes a “BGA” (Ball Grid Array) package, so that contacting conductor structures are connection solder spots for the solder balls of the “BGA” package.

Furthermore, a plurality of printed circuit board input and printed circuit board output contact terminals are, for example, arranged on the top and/or the bottom layers. They serve in one embodiment to connect the input and output contacts of the at least one device with at least one external device. In the case of the printed circuit board for a memory module, for instance, the control device is connected with an external memory controller.

For example, the printed circuit board input and printed circuit board output contact terminals are arranged along an edge of the printed circuit board. Thus, the printed circuit board can in a simple manner be plugged into a breadboard socket terminal strip—in the case of a printed circuit board for a memory module into a memory breadboard socket terminal strip—with the contact terminal strip formed along the edge by the contact terminals.

Finally, the printed circuit board, for example, includes, on the top and/or the bottom layer, a plurality of short conductor structures, “stubs”, which are each connected with predetermined ones of the printed circuit board input or printed circuit board output contact terminals or predetermined ones of the first or second high speed conductor structures through vias between the layers.

This largely avoids a crosstalk on the top and/or bottom layers of the high speed signals which are only guided over the short conductor structures to other signals which are guided in conductor structures of the upper or lower layers, and a noise feeding through the contact terminals of the devices which are arranged on the top and/or bottom layers, in one embodiment in the substrates of the semiconductor devices.

For example, the first and second high speed signals are, between predetermined ones of the contacting conductor structures for the at least one device which are, for example, designed in the form of contacting conductor structures for a “BGA” (Ball Grid Array) package, and predetermined ones of the vias which are each correspondingly connected with predetermined ones of the first or second high speed conductor structures, only guided through the short conductor structures.

Likewise, the first and second high speed signals on the top and/or bottom layers are, between predetermined ones of the printed circuit board input and/or printed circuit board output contact terminals and predetermined ones of the vias which are each correspondingly connected with predetermined ones of the first or second high speed structures, for example, only guided through the short conductor structures.

In one embodiment, at least one bus for the transmission of at least the first and second high speed signals is installed between the contacting conductor structures of the at least one device and the printed circuit board input and printed circuit board output contact terminals at least by parts of the predetermined conductor structures and by predetermined ones of the vias between the layers.

In accordance with a further development, the printed circuit board includes at least a first shielding layer directly above the first inner layer and at least a second shielding layer below the second inner layer.

For example, the first and/or the second shielding layers include at least one large-area—in one example a substantially area-wide—conductor structure which is destined to carry a respective substantially constant electric potential—for example, the ground potential. The conductor structures arranged on the first and/or the second shielding layers may serve as conductor structures for the ground potential for the high speed conductor structures on the first or second inner layers. Thus, the conductor impedances of the high speed conductor structures are more calculable and are correspondingly better to adapt to the source and load impedances associated with the respective high speed conductor structures.

A layer structure with a first and a second shielding layer above or below the layers carrying high speed signals avoids a crosstalk to conductor structures of the layers that are arranged thereabove or therebelow. In one embodiment, since this layer structure with shielded high speed conductor structures which are “buried” as deeply as possible, a crosstalk between the high speed conductor structures and the conductor structures on the top or bottom layer is substantially avoided.

In addition, by using the shielding layers, the high speed conductor structures are also shielded against the contact terminals of the devices. Thus, a noise feeding through the contact terminals of the devices into the devices, in one embodiment into the substrates of the integrated semiconductor devices, is largely avoided.

Thus, the above-mentioned layer structure is also superior to recent developments in the memory module design in which the high speed conductor structures are largely guided in the upper or lower layers. They correspondingly exhibit higher crosstalk to further conductor structures on the top and/or bottom layer of the printed circuit board and of higher noise feeding through the signals on the high speed conductor structures through the contact terminals of the devices, in one embodiment into the substrates of the semiconductor devices.

In a further design, the printed circuit board includes at least one further inner layer, substantially for guiding further signals, above the first shielding layer and/or below the second shielding layer. Thus, the first or second shielding layers also shield the further inner layer that is positioned thereabove or therebelow against the first or second inner layers. A crosstalk between the first or second high speed signals and the signals that are guided through the further inner layers is thus largely minimized.

For example, further signals of the at least one bus are, through the at least one further inner layer above the first shielding layer or below the second shielding layer, guided between predetermined ones of the contacting conductor structures for the at least one device and predetermined ones of the printed circuit board input and printed circuit board output contact terminals.

For reasons of high compatibility with existing drafts for printed circuit boards, in one embodiment printed circuit boards for common memory modules with specified dimensions, i.e. also specified printed circuit board thickness, printed circuit boards with a total of ten layers are used. The waiver of increasing the number of layers for additional high speed conductor structures, in one embodiment for printed circuit boards of recent memory module generations, has diverse features.

On the one hand, it is possible to further use, also for the new printed circuit boards, in one embodiment high speed conductor structures with known conductor impedance, for instance, from draft libraries of existing printed circuit board layout drafts. Furthermore, the danger that the dielectric thickness between the layers with respect to ten-layer drafts is significantly influenced does not exist.

It was namely above all the corresponding reduction of the dielectric thicknesses between the layers that significantly increased, without the introduction of additional shielding layers, in one embodiment with ground faces, the crosstalk between the layers that were thus spaced apart at less distance without a shielding layer therebetween. Finally, a small number of layers in a multi-layer printed circuit board, as a rule, also involves minor costs, which is of particular importance especially for a mass product such as a printed circuit board for a memory module.

To further increase, on the one hand, the above-mentioned low impedance in the feeding of the supply voltages, but, on the other hand, not to use too many layers for the carrying of the supply voltages, the printed circuit board includes two middle layers with two large-area conductor structures each for carrying a first and a second supply voltage potential.

In a further development, the two middle layers comprise, for carrying the first and second supply voltage potentials, conductor structures with a low surface resistivity—in one embodiment thicker conductor structures. Thus, it is possible to additionally reduce the impedances for the feeding of the corresponding first and second supply voltages, and the associated losses of available supply voltage at the devices across the pertinent impedances.

In one example, the thicker conductor structures result inherently on printed circuit boards with two middle layers in the case of two-stage press-fitted printed circuit boards with “blind” vias to either of the two middle layers.

Here, for example, a printed circuit board with ten layers is press-fitted from two prestages of the printed circuit board with five layers each in two stages. Thus, one of the middle layers each forms the bottom or top layer of the five-layer prestage of the printed circuit board. Vias to these layers are generated in that the five-layer prestages of the printed circuit board are drilled through at predetermined positions, and metallizing layers are deposited on the inner faces of the bores. Technologically, however, the depositing of the metallizing layer for the vias is, as a rule, associated with the deposition of an additional metallizing layer on the conductor structures of the outer layers, here especially on both middle layers, which form two of the outer layers of the five-layer prestages of the printed circuit board. Subsequently, the five-layer prestages of the printed circuit board are press-fitted to a ten-layer printed circuit board. Since the vias to the two middle layers are not necessarily congruent and since correspondingly, as a rule, no vias result which pass through the entire ten-layer printed circuit board, so that, correspondingly, the printed circuit board cannot be looked through, such vias are referred to as blind vias.

For the sake of completeness it is noted that not all the above-mentioned features have to be implemented by all and any of the above-mentioned or of further embodiments. The printed circuit board described cannot only be used for highly integrated memory modules with many memory devices, but for less highly integrated modules, in one embodiment for all kinds of “FBDIMM” memory modules. Thus, the guiding of the signals, in one embodiment the guiding of the high speed signals, can be implemented in a less compact manner with these modules, too. This means that an increase of the performance and/or of the reliability will result from the above-mentioned printed circuit board also for less highly integrated modules.

For example, the first and/or second high speed conductor structures are designed as differential conductor path pairs. This has the feature that interferences that couple in each of the conductor path pairs in the same manner will be deleted in the differential signal that is authoritative for the further processing.

In an exemplary design, at least one memory device—for example, a semiconductor memory device—is additionally arranged on the top and/or bottom layer, in one embodiment a “RAM” (Random Access Memory) semiconductor memory device, for example, a “DRAM” (Dynamic Random Access Memory). In one example, the control device is a hub chip communicating signals, in one embodiment control signals, between the at least one memory device and a memory controller.

In accordance with a further aspect there is provided a memory module with a novel printed circuit board as described above, wherein the memory module is, for example, an “FBDIMM” (Fully Buffered Dual-In Line Memory Module), a “DDR2” or “DDR3” “FBDIMM”.

In accordance with yet another aspect there is provided a memory module system on the basis of a novel memory module as described above.

Furthermore, one embodiment includes a method for manufacturing a printed circuit board, in one embodiment for a memory module.

In one process, a plurality of inner layers with predetermined conductor structures are formed. In so doing, at least one large-area conductor structure for guiding a respective substantially constant electric potential is formed in a partial process in at least one middle layer of the inner layers.

In a further partial process, predetermined first high speed conductor structures for guiding first high speed signals over the largest share of their guidance on the printed circuit board are formed in a first inner layer which is arranged directly above the middle layer or, in the case of a plurality of middle layers, above the top middle layer.

In yet a further partial process, predetermined second high speed conductor structures for guiding second high speed signals over the largest share of their guidance on the printed circuit board are formed in a second inner layer which is arranged directly below the middle layer or, in the case of a plurality of middle layers, below the bottom middle layer.

In a further process of the method, a top and a bottom layer are formed. In so doing, at least the following structures are formed on the top and/or bottom layers in at least one structuring step: a plurality of contacting conductor structures for at least one device, in one embodiment a control device, and a plurality of printed circuit board input and printed circuit board output contact terminals, for example, at a longitudinal edge of the printed circuit board.

In the scope of the structuring process of the outer layers, a plurality of short conductor structures are formed on the top and/or the bottom layers, which are destined to be connected through vias between the layers with predetermined ones of the printed circuit board input and/or printed circuit board output contact terminals and/or predetermined ones of the first and/or second high speed conductor structures.

In a further process, the layers are press-fitted to the printed circuit board in one or several stages.

In yet another process, the vias are formed between predetermined ones of the conductor structures of the layers.

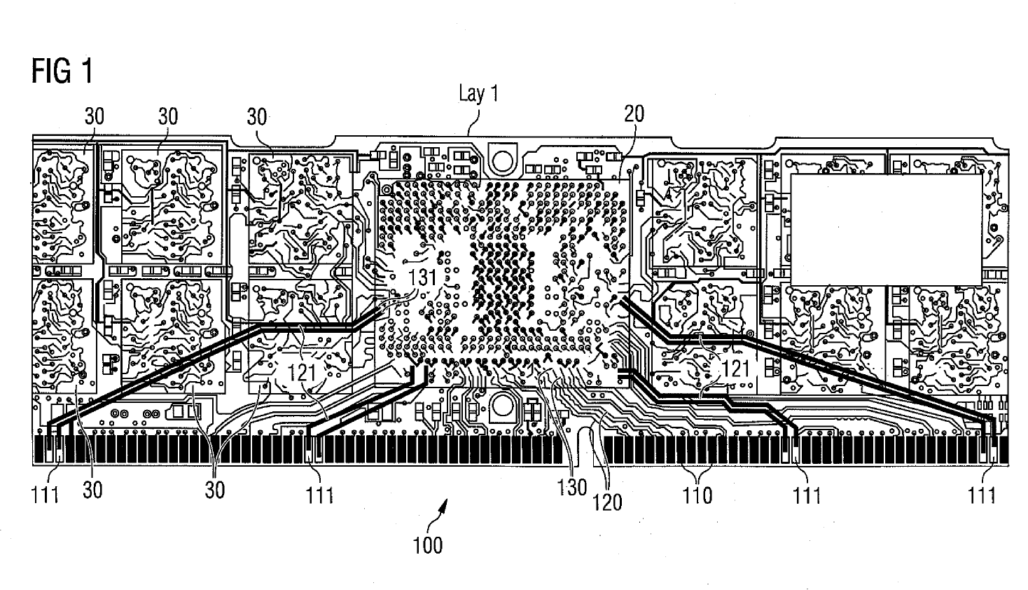

FIG. 1 illustrates a schematic top view of a section of a top layer Lay 1 of a printed circuit board for a “DDR2” “FBDIMM” memory module. The larger rectangular symbolic contour in the middle of the layer Lay 1 indicates the position of the control device 20. The memory devices 30 are, as is indicated by the six smaller symbolic rectangular contours each at the left and at the right of the control device 20, to be positioned pairwise in two rows in parallel to each other.

The control device 20 includes in the embodiment as a driver/control chip a hub chip for controlling the memory devices 30 and communicates on the memory module between an external (not illustrated) memory controller and the memory devices 30. For the communication between the control device 20 and the memory controller, a (signal) bus is installed therebetween.

Predetermined contacting conductor structures 130 for the control device 20 are connected with predetermined ones of the printed circuit board input and printed circuit board output contact terminals 110 through conductor structures. The printed circuit board input and printed circuit board output contact terminals 110 are, in accordance with a specification for a “DDR2” “FBDIMM” memory module with predetermined breadth, distance, number, grouping, etc., arranged in a contact terminal strip 100. This is indicated in FIG. 1 by the dense row of symbolic contact terminal faces at the lower edge of the layer Lay 1 of the printed circuit board.

In one embodiment also for the transmission of a high speed signal, predetermined contacting conductor structures 130 for the control device 20 are connected with predetermined printed circuit board input and printed circuit board output contact terminals 110 through a differential conductor path pair 120 as high speed conductor structures.

In a “DDR2” “SDRAM”-based memory module, memory cells of four consecutive memory addresses are read out with one read instruction, in a “DDR3” “SDRAM”-based memory module, however, eight. Correspondingly, in a printed circuit board for a “DDR3” “SDRAM”-based memory module, the number of high speed signals that have to be guided between the control device 20 and the contact terminal strip 100 will also increase.

Thus, for the draft of a printed circuit board for a “DDR3”-based “FBDIMM” memory module, there results the requirement—vis-à-vis the “DDR2”-based draft illustrated in FIG. 1—of guiding a total of eight additional differential conductor path pairs between further predetermined ones of the contacting conductor structures 131 of the control device 20 and further predetermined printed circuit board input and printed circuit board output contact terminals 111. Four of these eight additional differential conductor path pairs 121 are symbolized in FIG. 1 in the form of the thick lines.

Since the four additional differential conductor path pairs 121 cross numerous conductor structures in the conductor structure draft for the top layer Lay 1 for a printed circuit board of a “DDR2”-based “FBDIMM” memory module, it becomes clear that no sufficient space is available for the guiding of the four additional differential conductor path pairs 121 in a correspondingly designed upper layer Lay 1 for a printed circuit board of a “DDR3”-based “FBDIMM” memory module.

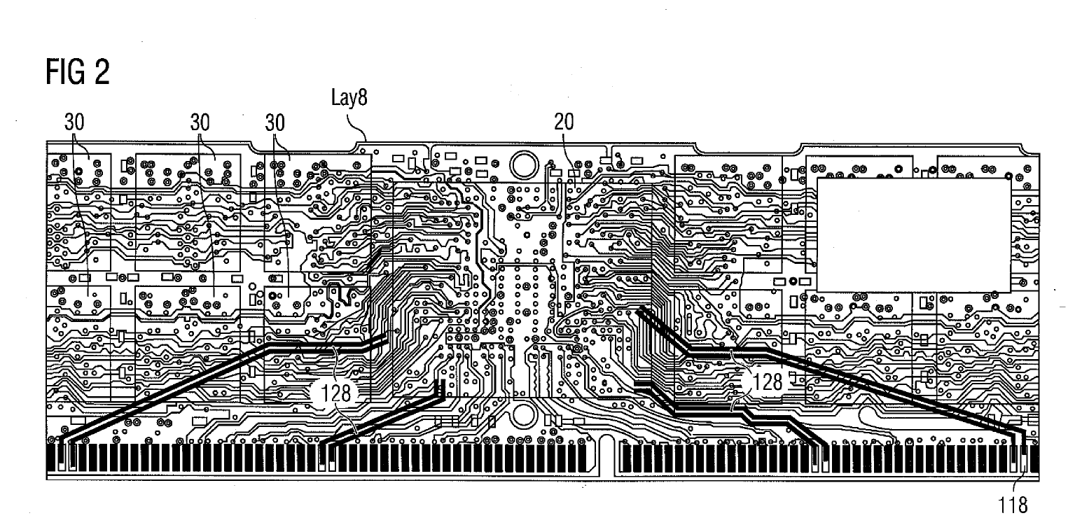

FIG. 2 illustrates the remaining four additional differential conductor path pairs 128 which would have to be supplemented according to the printed circuit board layout on a lower layer Lay 8 of a printed circuit board for a “DDR3”-based “FBDIMM” memory module with respect to a “DDR2”-based “FBDIMM” memory module. Since the layer Lay 8 has an even denser conductor structure net, the four additional differential conductor path pairs 128 in FIG. 2 cross even more conductor structures that are already available. This means that the corresponding supplementation of the layout of a printed circuit board of a “DDR2”-based “FBDIMM” memory module, in order to arrive at a printed circuit board layout for a “DDR3”-based “FBDIMM” memory module, is not possible due to the lack of space for guiding a total of eight additional differential conductor path pairs.

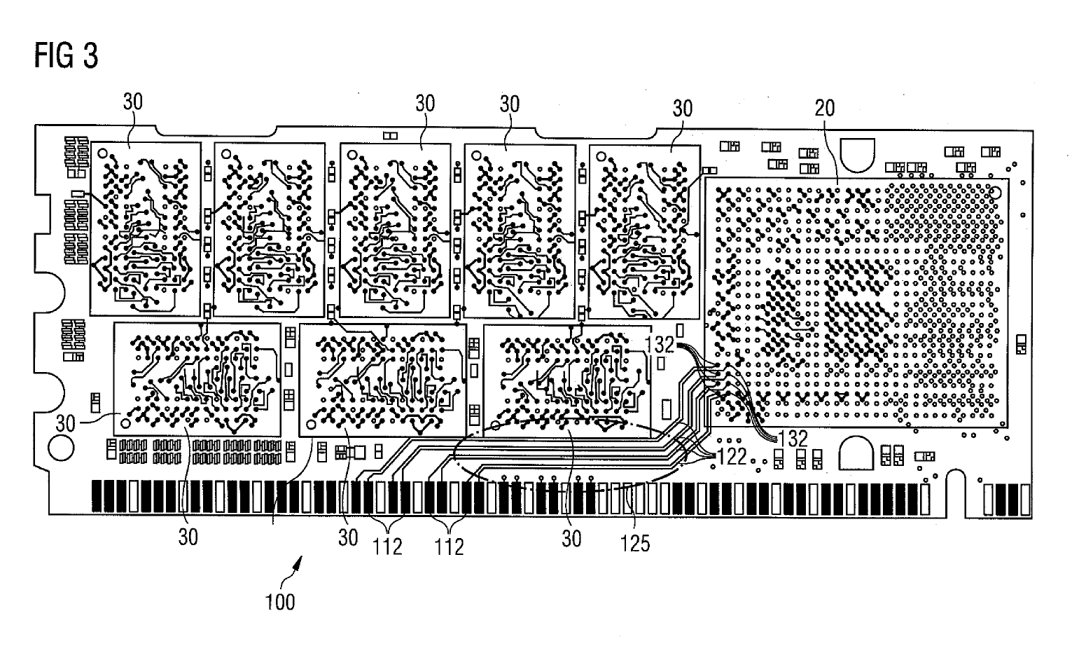

FIG. 3 illustrates a representation that is analog to that of FIG. 1 for an upper layer of a printed circuit board for a memory module which has been equipped in another way. The memory devices 30 of the lower row are arranged longitudinally instead of transversely. In the narrow corridor 125 between the lower memory devices 30 and the contact terminal strip 100, however, only four differential conductor path pairs 122 can be guided as high speed conductor structures of predetermined ones of the contacting conductor structures 132 for the control device 20 to predetermined ones of the printed circuit board input and printed circuit board output contact terminals 112.

FIG. 4 illustrates the layer structure of a printed circuit board for a “DDR2”-based “FBDIMM” memory module with ten layers Lay 1, Lay 2, . . . , and Lay 10. This arrangement is destined for a planar memory module draft in which a total of 36 memory devices is arranged, distributed over the top layer Lay 1 and the bottom layer Lay 10. In addition to the designations of the layers, designations of the signals or potentials which are carried at least over parts of the conductor structures of the respective layer and which are characteristic of this layer are indicated in FIG. 4.

Thus, FIG. 4 illustrates, for instance, that conductor structures for guiding the first high speed signals, designated by 1 HS, between the contacting conductor structures of the control device and the printed circuit board input and printed circuit board output contact terminals are distributed over the two layers Lay 1 and Lay 3 in a layer structure for a memory module.

Conductor structures for guiding the second high speed signals, designated by 2 HS, between the contacting conductor structures of the control device and the printed circuit board input and printed circuit board output contact terminals are even distributed over the four layers Lay 5, Lay 6, Lay 8, and Lay 10 in the layer structure for a memory module.

Due to the corresponding distribution of the high speed conductor structures over the layers mentioned, the layer structure including ten layers has, so as to avoid crosstalk between the different high speed signals, in one embodiment between first and second high speed signals, and so as to obtain controllable conductor impedances of the high speed conductor structures, a total of four layers Lay 2, Lay 4, Lay 7, and Lay 9 for the arrangement of ground potential faces, designated by GND. Since these layers are virtually not available for guiding other signals, and since the conductor structures for guiding the signals and direct voltage potentials, in one embodiment the supply voltage potentials VDD, VCC, are correspondingly more densely crowded on the remaining six layers.

In the layer structure according to FIG. 4, especially some of the first high speed signals are guided through “stripline” high speed conductor structures, which is usually associated with conductor impedances that are worse to check and which asymmetries with respect to the signals guided through differential conductor path pairs, in one embodiment micro strip conductor pairs.

FIG. 5 illustrates an embodiment of a layer structure for a printed circuit board of an “FBDIMM” memory module, in one embodiment a “DDR3”-based “FBDIMM” memory module, in accordance with one embodiment. The layer structure in FIG. 5 includes, like that in FIG. 4, ten layers.

Two middle layers Lay 5 and Lay 6 in accordance with one embodiment are provided. Large-area conductor structures which are destined to carry the supply voltage potentials VDD and VCC are arranged thereon. Thus, on the one hand, a low impedance of the feeding of the supply voltage potentials VDD and VCC to the devices to be arranged on the printed circuit board is ensured. On the other hand, the large-area conductor structures with the respective substantially constant potentials VDD, VCC ensure small crosstalk between the first 1 HS and second 2 HS high speed signals.

For guiding the first high speed signals 1 HS, a first inner layer Lay 4 is arranged above the top layer Lay 5 of the middle layers. It is destined to guide the first high speed signals 1 HS over the largest share of their guidance on the printed circuit board, i.e. over the widest distances between the contacting conductor structures of the control device and the printed circuit board input and printed circuit board output contact terminals at a longitudinal edge of the printed circuit board. The first inner layer Lay 4 that is substantially reserved for guiding the first high speed signals 1 HS, thus offers sufficient space for guiding all the first high speed signals 1 HS over differential conductor path pairs.

Correspondingly, for guiding the second high speed signals 2 HS, a second inner layer Lay 7 is arranged below the bottom layer Lay 6 of the middle layers. It is destined to guide the second high speed signals 2 HS over the largest share of their guidance on the printed circuit board. The second inner layer Lay 7 that is substantially reserved for guiding the second high speed signals 2 HS, thus offers sufficient space for guiding all the second high speed signals 2 HS over differential conductor path pairs.

For the shielding against signals on the top layers Lay 1 and Lay 2, a first shielding layer Lay 3 is positioned directly above the first inner layer Lay 4. A substantially area-wide conductor structure is arranged thereon, which is destined for carrying the mass potential GND and serves as a ground potential face for the first high speed conductor structures on the first inner layer Lay 4. Correspondingly, the first high speed conductor structures have checkable and predetermined conductor impedances. Likewise, the mass potential-carrying conductor structure of the layer Lay 3 also acts as a ground potential face for the conductor structures of the layer Lay 2.

In analogy, for the shielding against signals on the lower layers Lay 9 and Lay 10, a second shielding layer Lay 8 is positioned directly below the second inner layer Lay 7. A substantially area-wide conductor structure is arranged thereon, which is destined for carrying the ground potential GND and serves as a mass potential face for the second high speed conductor structures on the second inner layer Lay 7. Correspondingly, the second high speed conductor structures have checkable and predetermined conductor impedances. Likewise, the ground potential-carrying conductor structure of the layer Lay 8 also serves as a ground potential face for the conductor structures of the layer Lay 9.

By using this double utilization of the layers Lay 3 and Lay 8, two ground layers may be omitted vis-à-vis the layer structure in FIG. 4. Correspondingly, in one embodiment for the guiding of the further signals (e.g., the signals DQ, CA, CTRL, CLK), in one embodiment the further bus signals, two complete layers may be reserved with the layers Lay 2 and Lay 9. Thus, it is in turn possible to largely keep free the first inner layer Lay 4 and the second inner layer Lay 7 of conductor structures for guiding other signals than the first and second high speed signals.

For the embodiment in FIG. 5 it is assumed that the top layer Lay 1 is destined to place the control device thereon. In contrast to a layer structure as in FIG. 4, in one embodiment the top layer Lay 1 is also largely free from high speed conductor structures, again to avoid a crosstalk between the corresponding signals and to reduce the noise feeding into the devices through the contact terminals thereof, in one embodiment into the substrates of the semiconductor devices.

In one embodiment, the first high speed signals on the top layer Lay 1 are, by predetermined ones of the contacting conductor structures of the control device, guided only through short conductor structures (“1 HS stubs”), from where they are connected through predetermined vias to the first inner layer Lay 4 with the first end of predetermined first high speed conductor structures. These guide the first high speed signals over the largest share of their guidance on the printed circuit board. The respectively second end of the predetermined first high speed conductor structures is in turn connected with predetermined vias which guide the first high speed signals back to the top layer Lay 1. On the top layer Lay 1, the latter-mentioned vias are again connected with predetermined ones of the printed circuit board input or printed circuit board output contact terminals through short conductor structures (“1 HS stubs”) only.

In one embodiment, the second high speed signals on the bottom layer Lay 10 are, by predetermined ones of the printed circuit board input or printed circuit board output contact terminals, guided through short conductor structures (“2 HS stubs”) only, from where they are connected through predetermined vias to the second inner layer Lay 7 with the first end of predetermined second high speed conductor structures. These guide the second high speed signals over the largest share of their guidance on the printed circuit board. The respectively second end of the predetermined second high speed conductor structures is in turn connected with predetermined vias which guide the second high speed signals to the top layer Lay 1. On the top layer Lay 1, the latter-mentioned vias are again connected with predetermined ones of the contacting conductor structures of the control device via short conductor structures only.

This way, the mutual influencing of the high speed signals, the noise feeding into the devices, and the possible coupling of external interference signals in the high speed signals are minimized on the top layer Lay 1 and the bottom layer Lay 10 of the printed circuit board in accordance with an embodiment.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor component including a printed circuit board comprising:
a top layer and a bottom layer;
a middle layer between the top and bottom layers comprising at least one large-area conductor structure for guiding a respective substantially constant electric potential;
a first inner layer positioned above the middle layer and comprising first high speed conductor structures for guiding first high speed signals;
a second inner layer positioned below the middle layer comprising second high speed conductor structures for guiding second high speed signals;
a plurality of contacting conductor structures for a control device;
a plurality of printed circuit board input and printed circuit board output contact terminals; and
a plurality of conductor structures coupled within the layers through vias between the layers.

2. The semiconductor component of claim 1, wherein the plurality of conductor structures are coupled to the printed circuit board input and/or printed circuit board output contact terminals.

3. The semiconductor component of claim 1, wherein the plurality of conductor structures are coupled to the first and/or second high speed conductor structures.

4. The semiconductor component of claim 1 configured as an “FBDIMM” (Fully Buffered Dual-In Line Memory Module) module, a “DDR2” or “DDR3” “FBDIMM”.

5. A printed circuit board for a memory module, comprising:
a top layer, a bottom layer, and a plurality of stacked inner layers therebetween, each comprising predetermined conductor structures;
at least one middle layer comprising at least one large-area conductor structure for guiding a respective substantially constant electric potential;
wherein a first inner layer positioned above the middle layer comprises predetermined first high speed conductor structures for guiding first high speed signals;
wherein a second inner layer positioned below the middle layer comprises predetermined second high speed conductor structures for guiding second high speed signals;
wherein on the top and/or the bottom layers there are arranged at least:
a plurality of contacting conductor structures for at least one device, in particular a control device;
a plurality of printed circuit board input and printed circuit board output contact terminals; and
a plurality of conductor structures each connected with predetermined ones of said printed circuit board input and/or printed circuit board output contact terminals or predetermined ones of said first and/or second high speed conductor structures through vias between the layers.

6. The printed circuit board according to claim 5, wherein said first inner layer is positioned directly above said middle layer or, in the case of a plurality of middle layers, directly above the top middle layer, and/or wherein said second inner layer is positioned directly below said middle layer or, in the case of a plurality of middle layers, directly below the bottom middle layer.

7. The printed circuit board according to claim 5, wherein, between said contacting conductor structures of the at least one device and said printed circuit board input and printed circuit board output contact terminals, at least through parts of the predetermined conductor structures and through predetermined ones of the vias between the layers, at least one bus is installed for transmitting at least said first and second high speed signals.

8. The printed circuit board according to claim 5, comprising at least a first shielding layer directly above said first inner layer and at least a second shielding layer below said second inner layer.

9. The printed circuit board according to claim 8, wherein said first and/or said second shielding layers comprise at least one large-area conductor structure for guiding a respective substantially constant electric potential.

10. The printed circuit board according to claim 8, which comprises, above said first shielding layer and/or below said second shielding layer, at least one further inner layer substantially for guiding further signals, for guiding further signals of the at least one bus between predetermined ones of said contacting conductor structures for said at least one device and predetermined ones of said printed circuit board input and printed circuit board output contact terminals.

11. The printed circuit board according to claim 5, wherein said first and second high speed signals between predetermined ones of said contacting conductor structures for said at least one device, which are designed in the form of contacting conductor structures for a “BGA” (Ball Grid Array) package, and predetermined ones of the vias which are each correspondingly connected with predetermined ones of said first or second high speed conductor structures are guided through the short conductor structures only.

12. The printed circuit board according to claim 5, wherein said first and second high speed signals on said top and/or bottom layers between predetermined ones of said printed circuit board input and/or printed circuit board output contact terminals and predetermined ones of said vias which are each correspondingly connected with predetermined ones of said first or second high speed conductor structures are guided through the short conductor structures only.

13. The printed circuit board according to claim 5, comprising two middle layers with two respective large-area conductor structures for guiding a first and a second supply voltage potential.

14. The printed circuit board according to claim 13, wherein said two middle layers comprise conductor structures with a low surface resistivity for guiding said first and said second supply voltage potentials.

15. The printed circuit board according to claim 5, wherein said first and/or second high speed conductor structures are differential conductor path pairs.

16. The printed circuit board according to claim 5, wherein, on said top and/or bottom layers at least one memory device in particular a “RAM” (Random Access Memory) semiconductor memory device, a “DRAM” (Dynamic Random Access Memory) is additionally arranged, and wherein said control device is a hub chip which communicates signals, in particular control signals, between said at least one memory device and a memory controller.

17. A memory module system comprising at a printed circuit board according to claim 5.

18. A method for manufacturing a printed circuit board comprising:
forming a plurality of inner layers with predetermined conductor structures;
forming a top and a bottom layer;
forming a plurality of contacting conductor structures for at least one control device,
forming a plurality of printed circuit board input and printed circuit board output contact terminals, at a longitudinal edge of said printed circuit board,
forming a plurality of short conductor structures that are configured to be connected with predetermined ones of said printed circuit board input and/or printed circuit board output terminals and/or predetermined ones of said first and/or second high speed conductor structures through vias between the layers; and
one- or multi-stage press-fitting the layers to the printed circuit board.

19. The method of claim 18:
wherein in at least one middle layer of said inner layers at least one large-area conductor structure for guiding a respective substantially constant electric potential is formed;
wherein in a first inner layer which is positioned above said middle layer, predetermined first high speed conductor structures are formed; and
wherein in a second inner layer which is positioned below said middle layer, predetermined second high speed conductor structures are formed.

20. The method of claim 19 additionally comprising forming the vias between predetermined ones of the conductor structures of the layers.
